(19) United States
(12) Patent Application Publication
(10) Pub. No.: US 2026/0033215 A1
(43) Pub. Date: Jan. 29, 2026

(54) DISPLAY PANEL AND ELECTRONIC APPARATUS

(71) Applicant: Samsung Display Co., Ltd., Yongin-si (KR)

(72) Inventors: Youngjoo Nam, Yongin-si (KR); Dongwan Choi, Yongin-si (KR); Youngbin Kim, Yongin-si (KR); Jooyoung Kim, Yongin-si (KR)

(21) Appl. No.: 19/084,499

(22) Filed: Mar. 19, 2025

(30) Foreign Application Priority Data
Jul. 29, 2024 (KR) 10-2024-0100545

(51) Int. Cl. H10K 59/80; G09G 3/3233; H10K 59/131

(52) U.S. Cl. CPC H10K 59/873; G09G 3/3233; H10K 59/131; G09G 2300/0426; G09G 2300/0819; G09G 2300/0842

(57) ABSTRACT

Provided are a display panel and an electronic apparatus. The display panel includes a substrate, a display layer above the substrate, a display driver above the substrate, and apart from the display layer, and an encapsulation member above the display layer, configured to shield the display layer and the substrate, and defining an opening recessed toward the display layer to expose the display driver.

### CROSS-REFERENCE TO RELATED APPLICATIONS

The present application claims priority to, and the benefit of, Korean Patent Application No. 10-2024-0100545, filed on Jul. 29, 2024, in the Korean Intellectual Property Office, the entire disclosure of which is incorporated herein by reference.

### BACKGROUND

### 1. Field

One or more embodiments relate to a display panel and an electronic apparatus.

### 2. Description of the Related Art

Mobile electronic apparatuses are widely used. As mobile electronic apparatuses, recently, tablet personal computers (PCs) have been widely used as well as miniaturized electronic apparatuses such as mobile phones.

To support various functions, for example, to provide a user with visual information, such as images, the mobile electronic apparatuses include a display panel. Recently, as the parts configured to drive a display panel have been miniaturized, the proportion of the display panel in an electronic apparatus has gradually increased, and a structure that may bend to a corresponding angle with respect to a flat state is also under development.

### SUMMARY

In a display panel, a display driver may be located on a substrate of the display panel to display various images, and a display controller may be connected to the display panel. In this case, various wirings may be located between the display driver and a display area of the display panel, depending on the position of the display driver, the number of display drivers, and whether the display controller is connected. When exposed to the outside, the wirings may be damaged. In addition, because the display controller may not stably supply power to the display panel depending on whether the display controller is connected, not only a malfunction of the display panel may be caused, but also a structure may be complicated to stably connect the display controller to the display panel. One or more embodiments include a display panel and an electronic apparatus with a reduced exposure range of wirings between a display driver and a display area of the display panel, capable of maintaining a robust connection between the display panel and a display controller.

Additional aspects will be set forth in part in the description which follows and, in part, will be apparent from the description, or may be learned by practice of the presented embodiments of the disclosure.

According to one or more embodiments, a display panel includes a substrate, a display layer above the substrate, a display driver above the substrate, and apart from the display layer, and an encapsulation member above the display layer, configured to shield the display layer and the substrate, and defining an opening recessed toward the display layer to expose the display driver.

The substrate may include a substrate protrusion protruding away from the display layer to correspond to a portion on which the display driver is located.

The display panel may further include a display controller connected to the substrate, configured to transfer a signal to the display driver, and defining a recess recessed away from the substrate protrusion to correspond to the substrate protrusion.

The display panel may further include a display controller connected to the substrate, configured to transfer a signal to the display driver, and including a portion overlapping the substrate protrusion in a plan view.

The display panel may further include a display controller connected to the substrate, and configured to transfer a signal to the display driver.

The display panel may further include a connection member connecting the display controller to the substrate.

The display controller may be directly connected to the substrate.

The encapsulation member may include an encapsulation substrate facing the substrate, and defining the opening, and a sealing member between the encapsulation substrate and the substrate.

The encapsulation member may cover the display layer and defines the opening.

At least a portion of a planar shape of the opening may be an oblique line.

According to one or more embodiments, a display panel includes a substrate including a display area and a peripheral area, a display driver in the peripheral area, and a display controller connected to the substrate, and configured to transfer a signal to the display driver, wherein the display controller is in direct contact with the substrate and connected to the substrate in at least two portions.

The display controller may include a display circuit board, and a connector protruding from the display circuit board toward the substrate, and integrally formed with the display circuit board.

The display panel may further include a connection member apart from the connector, and connecting the display circuit board to the substrate.

The connector may include a rigid-flexible printed circuit board.

The substrate may include a substrate protrusion protruding toward the display controller.

The display driver may be above the substrate such that at least a portion thereof overlaps the substrate protrusion.

The display controller may define a recess recessed in a direction away from the substrate protrusion, and having a shape corresponding to the substrate protrusion.

At least a portion of the display controller may overlap the substrate.

According to one or more embodiments, a display panel includes a substrate, a display layer above the substrate, an encapsulation member above the display layer, and shielding the display layer and the substrate, a display driver above the substrate, and apart from the display layer, and a display controller connected to the substrate, and configured to transfer a signal to the display driver, wherein the substrate includes a substrate protrusion protruding to the display controller, and wherein the display controller defines a recess recessed in a direction away from the substrate protrusion, and having a shape corresponding to the substrate protrusion.

The display panel may further include a connection member connecting the display controller to the substrate protrusion.

The display driver may be above the substrate, and may correspond to the substrate protrusion.

According to one or more embodiments, an electronic apparatus includes a housing, and a display panel inside the housing, and including a substrate, a display layer above the substrate, an encapsulation member above the display layer, shielding the display layer and the substrate, and defining an opening recessed toward the display layer, and a display driver above the substrate, apart from the display layer, and exposed by the opening.

The substrate may include a substrate protrusion protruding in a direction away from the display layer to correspond to a location of the display driver.

The electronic apparatus may further include a display controller connected to the substrate, configured to transfer a signal to the display driver, and defining a recess recessed in a direction away from the substrate protrusion and having a shape corresponding to the substrate protrusion.

At least a portion of the display controller may be above the substrate to overlap the substrate protrusion.

The electronic apparatus may further include a display controller connected to the substrate, and configured to transfer a signal to the display driver.

The electronic apparatus may further include a connection member connecting the display controller to the substrate.

The display controller may be directly connected to the substrate.

The encapsulation member may include an encapsulation substrate facing the substrate, and defining the opening, and a sealing member between the encapsulation substrate and the substrate.

The encapsulation member may cover the display layer, and may define the opening.

At least a portion of a planar shape of the opening may be an oblique line.

These and/or other aspects will become apparent and more readily appreciated from the following detailed description of the embodiments, the accompanying drawings, and claims.

### BRIEF DESCRIPTION OF THE DRAWINGS

The above and other aspects of embodiments of the disclosure will be more apparent from the following description taken in conjunction with the accompanying drawings, in which:

FIG. 1 is a schematic plan view of a display panel according to one or more embodiments;

FIG. 2 is a schematic cross-sectional view of the display panel, taken along the line A-A′ of FIG. 1;

FIG. 3 is a schematic cross-sectional view of the display panel, taken along the line C-C′ of FIG. 1;

FIG. 4 is a circuit diagram of a pixel circuit of the display panel shown in FIG. 1;

FIG. 5 is a schematic cross-sectional view of a display panel according to one or more other embodiments;

FIG. 6 is a schematic plan view of a display panel according to one or more other embodiments;

FIG. 7 is a cross-sectional view of the display panel 50, taken along the line B-B′ of FIG. 6;

FIG. 8 is a schematic cross-sectional view of a first region of FIG. 7;

FIG. 9 is a schematic cross-sectional view of a second region of FIG. 7;

FIG. 10 is a schematic plan view of a portion of a display panel according to one or more other embodiments;

FIG. 11 is a schematic plan view of a portion of a display panel according to one or more other embodiments;

FIG. 12 is a schematic plan view of a display panel according to one or more other embodiments;

FIG. 13 is a schematic plan view of a display panel according to one or more other embodiments;

FIG. 14 is a schematic plan view of a display panel according to one or more other embodiments;

FIG. 15 is a schematic plan view of a display panel according to one or more other embodiments;

FIG. 16 is a schematic plan view of a display panel according to one or more other embodiments; and

FIG. 17 is a schematic perspective view of an electronic apparatus including a display panel according to embodiments.

### DETAILED DESCRIPTION

Aspects of some embodiments of the present disclosure and methods of accomplishing the same may be understood more readily by reference to the detailed description of embodiments and the accompanying drawings. The described embodiments are provided as examples so that this disclosure will be thorough and complete, and will fully convey the aspects of the present disclosure to those skilled in the art. Accordingly, processes, elements, and techniques that are redundant, that are unrelated or irrelevant to the description of the embodiments, or that are not necessary to those having ordinary skill in the art for a complete understanding of the aspects of the present disclosure may be omitted. Unless otherwise noted, like reference numerals, characters, or combinations thereof denote like elements throughout the attached drawings and the written description, and thus, repeated descriptions thereof may be omitted.

The described embodiments may have various modifications and may be embodied in different forms, and should not be construed as being limited to only the illustrated embodiments herein. The use of “can,” “may,” or “may not” in describing an embodiment corresponds to one or more embodiments of the present disclosure.

A person of ordinary skill in the art would appreciate, in view of the present disclosure in its entirety, that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

In the drawings, the relative sizes of elements, layers, and regions may be exaggerated for clarity and/or descriptive purposes. In other words, because the sizes and thicknesses of elements in the drawings are arbitrarily illustrated for convenience of description, the disclosure is not limited thereto. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Various embodiments are described herein with reference to sectional illustrations that are schematic illustrations of embodiments and/or intermediate structures. As such, variations from the shapes of the illustrations as a result of, for example, manufacturing techniques and/or tolerances, are to be expected. Further, specific structural or functional descriptions disclosed herein are merely illustrative for the purpose of describing embodiments according to the concept of the present disclosure. Thus, embodiments disclosed herein should not be construed as limited to the illustrated shapes of elements, layers, or regions, but are to include deviations in shapes that result from, for instance, manufacturing.

For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place.

Spatially relative terms, such as “beneath,” “below,” “lower,” “lower side,” “under,” “above,” “upper,” “over,” “higher,” “upper side,” “side” (e.g., as in “sidewall”), and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below,” “beneath,” “or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include stack, face or facing, extending over, covering, or partly covering or any other suitable term as would be appreciated and understood by those of ordinary skill in the art. The expression “not overlap” may include meaning, such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

It will be understood that when an element, layer, region, or component (e.g., an apparatus, a device, a circuit, a wire, an electrode, a terminal, a conductive film, etc.) is referred to as being “formed on,” “on,” “connected to,” or “(operatively, functionally, or communicatively) coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. In addition, this may collectively mean a direct or indirect coupling or connection and an integral or non-integral coupling or connection. For example, when a layer, region, or component is referred to as being “electrically connected” or “electrically coupled” to another layer, region, or component, it can be directly electrically connected or coupled to the other layer, region, and/or component or one or more intervening layers, regions, or components may be present. The one or more intervening components may include a switch, a transistor, a resistor, an inductor, a capacitor, a diode and/or the like. Accordingly, a connection is not limited to the connections illustrated in the drawings or the detailed description and may also include other types of connections. In describing embodiments, an expression of connection indicates electrical connection unless explicitly described to be direct connection, and “directly connected/directly coupled,” or “directly on,” refers to one component directly connecting or coupling another component, or being on another component, without an intermediate component.

In addition, in the present specification, when a portion of a layer, a film, an area, a plate, or the like is formed on another portion, a forming direction is not limited to an upper direction but includes forming the portion on a side surface or in a lower direction. On the contrary, when a portion of a layer, a film, an area, a plate, or the like is formed “under” another portion, this includes not only a case where the portion is “directly beneath” another portion but also a case where there is further another portion between the portion and another portion. Meanwhile, other expressions describing relationships between components, such as “between,” “immediately between” or “adjacent to” and “directly adjacent to,” may be construed similarly. It will be understood that when an element or layer is referred to as being “between” two elements or layers, it can be the only element or layer between the two elements or layers, or one or more intervening elements or layers may also be present.

For the purposes of this disclosure, expressions such as “at least one of,” or “any one of,” or “one or more of” when preceding a list of elements, modify the entire list of elements and do not modify the individual elements of the list. For example, “at least one of X, Y, and Z,” “at least one of X, Y, or Z,” “at least one selected from the group consisting of X, Y, and Z,” and “at least one selected from the group consisting of X, Y, or Z” may be construed as X only, Y only, Z only, any combination of two or more of X, Y, and Z, such as, for instance, XYZ, XY, YZ, and XZ, or any variation thereof. Similarly, the expressions “at least one of A and B” and “at least one of A or B” may include A, B, or A and B. As used herein, “or” generally means “and/or,” and the term “and/or” includes any and all combinations of one or more of the associated listed items. For example, the expression “A and/or B” may include A, B, or A and B. Similarly, expressions such as “at least one of,” “a plurality of,” “one of,” and other prepositional phrases, when preceding a list of elements, modify the entire list of elements and do not modify the individual elements of the list. When “C to D” is stated, it means C or more and D or less, unless otherwise specified.

It will be understood that, although the terms “first,” “second,” “third,” etc., may be used herein to describe various elements, components, regions, layers and/or sections, these elements, components, regions, layers and/or sections should not be limited by these terms. These terms do not correspond to a particular order, position, or superiority, and are only used to distinguish one element, member, component, region, area, layer, section, or portion from another element, member, component, region, area, layer, section, or portion. Thus, a first element, component, region, layer or section described below could be termed a second element, component, region, layer or section, without departing from the spirit and scope of the present disclosure. The description of an element as a “first” element may not require or imply the presence of a second element or other elements. The terms “first,” “second,” etc. may also be used herein to differentiate different categories or sets of elements. For conciseness, the terms “first,” “second,” etc. may represent “first-category (or first-set),” “second-category (or second-set),” etc., respectively.

In the examples, the x-axis, the y-axis, and/or the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. The same applies for first, second, and/or third directions.

The terminology used herein is for the purpose of describing embodiments only and is not intended to be limiting of the present disclosure. As used herein, the singular forms “a” and “an” are intended to include the plural forms as well, while the plural forms are also intended to include the singular forms, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

When one or more embodiments may be implemented differently, a specific process order may be performed differently from the described order. For example, two consecutively described processes may be performed substantially at the same time or performed in an order opposite to the described order.

As used herein, the terms “substantially,” “about,” “approximately,” and similar terms are used as terms of approximation and not as terms of degree, and are intended to account for the inherent deviations in measured or calculated values that would be recognized by those of ordinary skill in the art. For example, “substantially” may include a range of +/−5% of a corresponding value. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within +30%, 20%, 10%, 5% of the stated value. Further, the use of “may” when describing embodiments of the present disclosure refers to “one or more embodiments of the present disclosure.” Furthermore, the expression “being the same” may mean “being substantially the same”. In other words, the expression “being the same” may include a range that can be tolerated by those of ordinary skill in the art. The other expressions may also be expressions from which “substantially” has been omitted.

Also, any numerical range disclosed and/or recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein, and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein. All such ranges are intended to be inherently described in this specification such that amending to expressly recite any such subranges would comply with the requirements of 35 U.S.C. § 112 (a) and 35 U.S.C. § 132 (a).

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

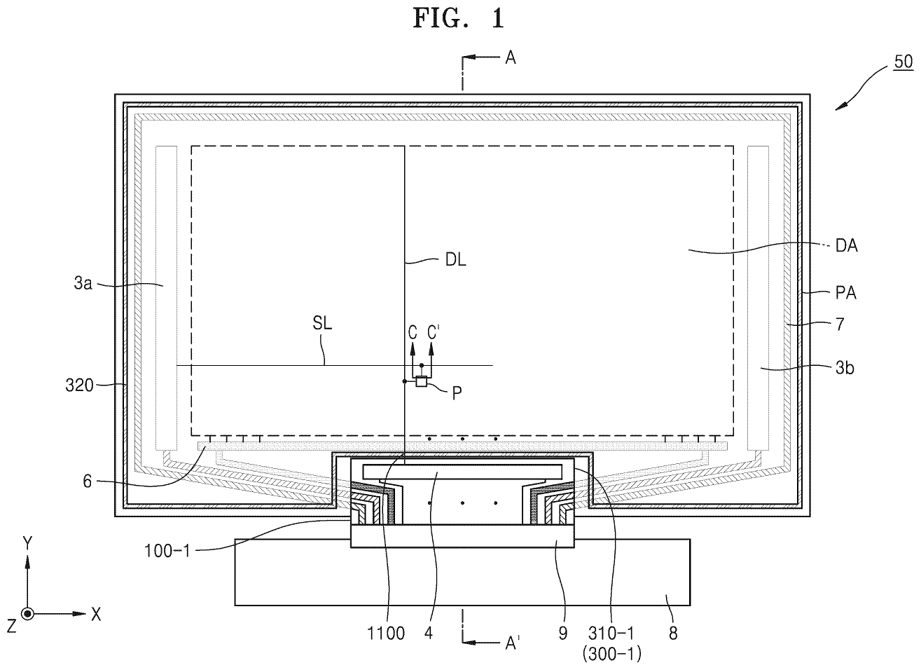

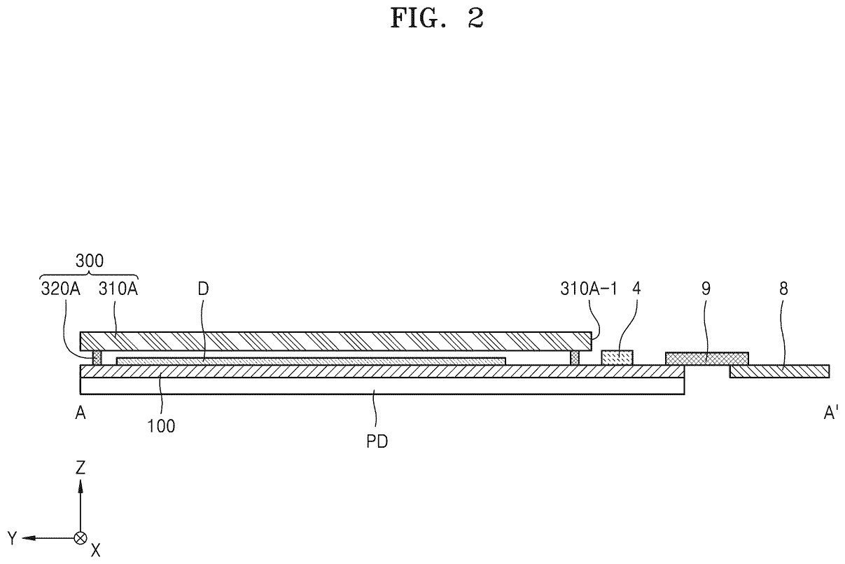

FIG. 1 is a schematic plan view of a display panel 50 according to one or more embodiments. FIG. 2 is a schematic cross-sectional view of the display panel 50, taken along the line A-A′ of FIG. 1.

Referring to FIGS. 1 and 2, the display panel 50 may include a substrate 100, a display layer D, an encapsulation member 300, a protective member PD, a display driver 4, a connection member 9, and a display controller 8.

The display layer D and the display driver 4 may be located on the substrate 100 (as used herein, “located on” may mean “above”). The display layer D may be isolated from the outside by being shielded by the substrate 100 and the encapsulation member 300. In this case, the encapsulation member 300 may include a sealing member 320A and an encapsulation substrate 310A. The encapsulation substrate 310A may include an equal or similar material to that of the substrate 100.

The protective member PD may be located on (e.g., below) the lower surface of the substrate 100. In this case, the protective member PD may absorb external impacts. The protective member PD may include a plurality of layers. As an example, the protective member PD may include a first layer, a second layer, and a third layer that are sequentially stacked. The first layer may have an embossed shape. As an example, the first layer may include a plurality of protuberances. Each protuberance may protrude toward the display panel 50. In this case, the upper surface of the first layer may have an uneven shape. In this case, the first layer may have adhesive force. Through this, the first layer may be attached to the rear surface of the substrate 100 of the display panel 50. In addition, the first layer may absorb external impacts through the embossed shape. The second layer may be located on one surface of the first layer. In this case, the second layer may include a porous material. Through this, the second layer may not only absorb impacts, but also may discharge heat from the display panel 50 to the outside. The third layer may include metal, and may be located on one side of the second layer. As an example, the third layer may include aluminum. In this case, the third layer may have a plate shape, and may cover the rear surface of the second layer entirely.

In the display panel 50, sub-pixels P located in a display area DA may be configured to emit red, green, and blue light by using light-emitting diodes located in relevant positions corresponding to respective sub-pixels P. Transistors and signal lines (e.g., data lines DL and scan lines SL) may be located in the display area DA, wherein the transistors are electrically connected to the light-emitting diodes, and the signal lines are electrically connected to a storage capacitor. The data lines DL may extend in a y direction in the display area DA, and the scan lines SL may extend in an x direction in the display area DA.

A peripheral area PA may be outside the display area DA, and may surround the display area DA entirely (e.g., in plan view).

First and second scan drivers 3a and 3b may be located in the peripheral area PA, and may be electrically connected to the scan lines SL. In one or more embodiments, some of the scan lines SL may be electrically connected to the first scan driver 3a, and the rest of the scan lines SL may be connected to the second scan driver 3b. The first and second scan drivers 3a and 3b may be configured to generate scan signals, and the generated scan signals may be transferred to a transistor electrically connected to a light-emitting diode through the scan line SL.

The first and second scan drivers 3a and 3b may be located on two opposite sides of the display area DA. As an example, as shown in FIG. 1, the first scan driver 3a may be located on the left of the display area DA, and the second scan driver 3b may be located on the right of the display area DA. In one or more other embodiments, one of the first and second scan drivers 3a and 3b may be omitted.

A driving voltage supply line 6 may be located in the peripheral area PA. The driving voltage supply line 6 may be located between one side of the substrate 100 in which a terminal section is located, and the display area DA.

A common voltage supply line 7 may be located in the peripheral area PA, and may have a loop shape having one open side and extending along the display area DA. The common voltage supply line 7 may have an overall U-shape. The common voltage supply line 7 may extend along the other sides except for one side of the substrate 100 in which the terminal section is located. Accordingly, the first scan driver 3a may be located between one portion of the common voltage supply line 7 and the display area DA, and the second scan driver 3b may be located between another portion of the common voltage supply line 7 and the display area DA.

The display driver 4 may be located in the peripheral area PA. The display driver 4 may be located between one side of the substrate 100 in which the terminal section is located, and the display area DA. The display driver 4 may include a data driver. In the present specification, the display driver 4 may represent a data driver. The display driver 4 may be electrically connected to a pad terminal located therebelow. Data signals generated by the display driver 4 (e.g., the data driver) may be transferred to a signal line located in the display area DA (e.g., the data line DL) through a connection line 1100 located in the peripheral area PA. Although it is shown in FIG. 2 that the display driver 4 is directly located on the substrate 100, the disclosure is not limited thereto. A portion of the display layer D may extend to the peripheral area PA, and the display driver 4 may be located on the portion of the display layer D extending to the peripheral area PA.

The terminal section may include terminals. The terminals may be electrically connected to a controller located on the display controller 8 by not being covered by an insulating layer, and by being exposed. In this case, the display controller 8 may be connected to the terminal section through the connection member 9. In this case, the connection member 9 may include a flexible printed circuit board. A controller SC may generate control signals for controlling the first and second scan drivers 3a and 3b, and the display driver 4, and generated control signals may be transferred to the first and second scan drivers 3a and 3b and the display driver 4 through the terminals. The controller may transfer a driving voltage and a common voltage to the driving voltage supply line 6 and the common voltage supply line 7, respectively, through the terminals. In one or more embodiments, at least a portion of the connection member 9 may bend. As an example, a portion of the connection member 9 located between the substrate 100 and the display controller 8 may bend. In this case, the display controller 8 may be located on/below the rear surface of the display area DA.

The shape of the substrate 100 may be different from the shape of the encapsulation substrate 310A. As an example, the substrate 100 may include a substrate protrusion 100-1 protruding in a direction away from the display area DA. In this case, the substrate 100 may have a ‘T’ shape. In addition, the encapsulation substrate 310A may include, or define, an opening 310A-1 in which at least a portion is recessed to the display area DA. In this case, the encapsulation substrate 310A may have a ‘C’ shape. In this case, the sealing member 320A may be located at the edge portion of the encapsulation substrate 310A, and may form a closed-loop to surround the edge of the display layer D in a plan view. In addition, the planar shape of the sealing member 320A may be similar to the planar shape of the encapsulation substrate 310A.

In this case, the substrate protrusion 100-1 and the opening 310A-1 may correspond to each other. In addition, the display driver 4 may correspond to the substrate protrusion 100-1, and may be located inside the opening 310A-1. At least a portion of the display driver 4 may overlap the substrate protrusion 100-1 in a plan view.

In this case, because the encapsulation substrate 310A and the sealing member 320A correspond to the edge of the substrate 100 as much as possible or suitable, the encapsulation substrate 310A and the sealing member 320A may shield at least a portion of at least one of a wiring connected from the first scan driver 3a to the terminal, a wiring connected from the second scan driver 3b to the terminal, a wiring connected from the driving voltage supply line 6 to the terminal, or a wiring connected from the common voltage supply line 7 to the terminal, or the connection line 1100. Through this, it is possible to reduce an area through which at least one of a wiring connected from the first scan driver 3a to the terminal, a wiring connected from the second scan driver 3b to the terminal, a wiring connected from the driving voltage supply line 6 to the terminal, or a wiring connected from the common voltage supply line 7 to the terminal, or the connection line 1100 is exposed to the outside.

Accordingly, in the display panel 50, because areas in which the wirings around the display driver 4 are shielded by the encapsulation substrate 310A are increased, damage or contamination of the wirings around the display driver 4 due to exposure to the outside may be reduced.

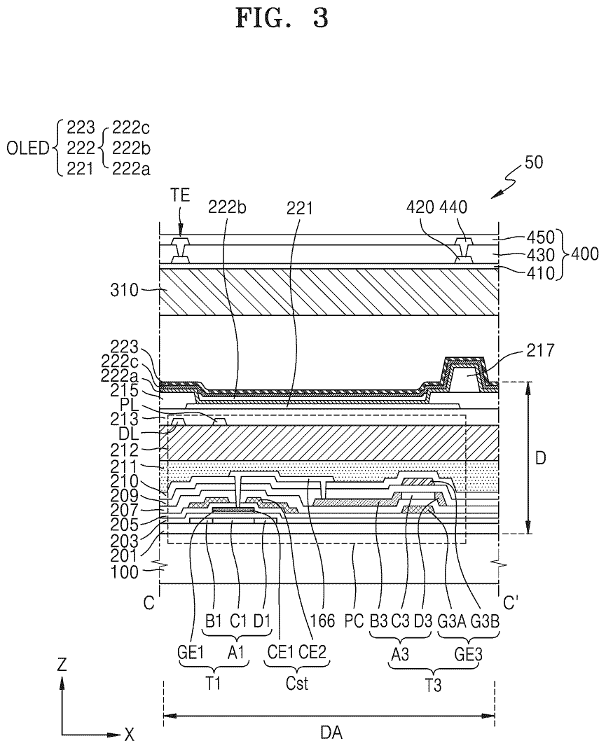

FIG. 3 is a schematic cross-sectional view of the display panel 50, taken along the line C-C′ of FIG. 1.

Referring to FIG. 3, the display panel 50 may include the substrate 100, the display layer D, the sealing member 320A, the encapsulation substrate 310A, and an input-sensing layer 400.

The display layer D may include a sub-pixel circuit PC and a light-emitting diode located in the display area DA of the display panel 50. In this case, the light-emitting diode may include an organic light-emitting diode OLED. Referring to FIG. 3, the display layer D may include layers from a buffer layer 201 to a spacer 217 on the substrate 100.

The substrate 100 may include glass or polymer resin. In one or more embodiments, the substrate 100 may have a stack structure in which a base layer including a polymer resin and a barrier layer including an inorganic insulating material, such as silicon oxide or silicon nitride, are alternately stacked. In the case where the substrate 100 includes the stack structure of the base layer of the polymer resin and the barrier layer of the inorganic insulating material, as described above, because the flexibility of the display panel improves as described above with reference to FIG. 1, a foldable display panel may be provided.

The polymer resin may include polyethersulfone, polyarylate, polyetherimide, polyethylene naphthalate, polyethylene terephthalate, polyphenylene sulfide, polyimide, polycarbonate, cellulose tri acetate, cellulose acetate propionate, or the like.

The sub-pixel circuit PC may be formed on the substrate 100, and the light-emitting diode (e.g., the organic light-emitting diode OLED) may be formed on the sub-pixel circuit PC.

The buffer layer 201 may be formed on the substrate 100 before the sub-pixel circuit PC is formed to reduce or prevent permeation of impurities into the sub-pixel circuit PC. The buffer layer 201 may include an inorganic insulating material, such as silicon nitride, silicon oxynitride, and/or silicon oxide, and may include a single-layered structure or a multi-layered structure including the above inorganic insulating materials.

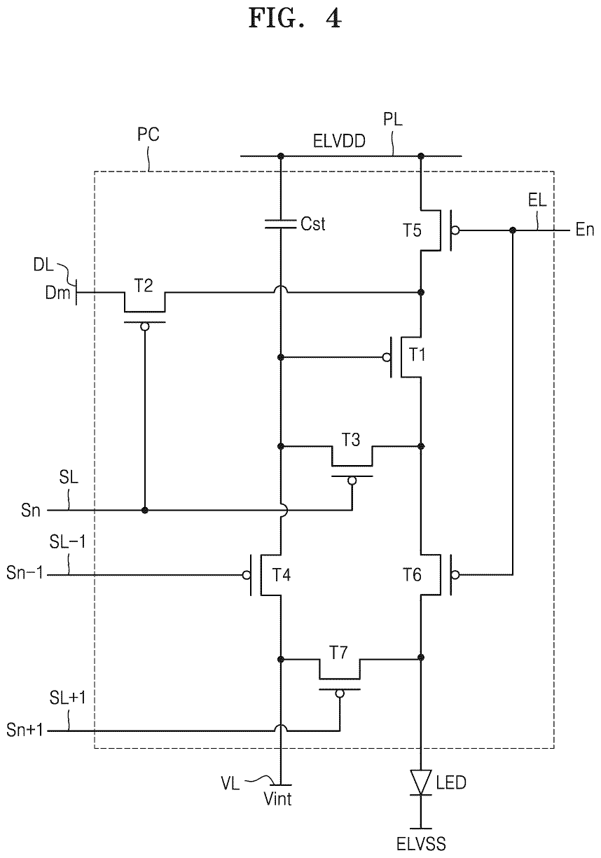

As described above with reference to FIG. 4, the sub-pixel circuit PC may include the plurality of transistors and the storage capacitor. With regard to this, FIG. 3 shows a first thin-film transistor T1, a third thin-film transistor T3, and a storage capacitor Cst.

The first thin-film transistor T1 may include a semiconductor layer (referred to as a first semiconductor layer A1) on the buffer layer 201, and a gate electrode (referred to as a first gate electrode GE1) overlapping a channel region C1 of the first semiconductor layer A1. The first semiconductor layer A1 may include a silicon-based semiconductor material (e.g., polycrystalline silicon). The first semiconductor layer A1 may include the channel region C1, a first region B1, and a second region D1, wherein the first region B1 and the second region D1 are respectively located on two opposite sides of the channel region C1. The first region B1 and the second region D1 are regions including impurities of higher concentration than that of the channel region C1. One of the first region B1 and the second region D1 may correspond to a source region, and the other may correspond to a drain region.

A first gate-insulating layer 203 may be located between the first semiconductor layer A1 and the first gate electrode GE1. The first gate-insulating layer 203 may include an inorganic insulating material, such as silicon nitride, silicon oxynitride, and/or silicon oxide, and may include a single-layered structure or a multi-layered structure including the above inorganic insulating materials.

The first gate electrode GE1 may include a conductive material including molybdenum (Mo), aluminum (Al), copper (Cu), and titanium (Ti), and may have a single-layered structure or a multi-layered structure including the above materials.

The storage capacitor Cst may include a lower electrode CE1 and an upper electrode CE2 overlapping each other. In one or more embodiments, the lower electrode CE1 of the storage capacitor Cst may include the first gate electrode GE1. In other words, the first gate electrode GE1 may include, or may be, the lower electrode CE1 of the storage capacitor Cst. As an example, the first gate electrode GE1 and the lower electrode CE1 of the storage capacitor Cst may be integrally formed.

A first interlayer insulating layer 205 may be located between the lower electrode CE1 and the upper electrode CE2 of the storage capacitor Cst. The first interlayer insulating layer 205 may include an inorganic insulating material, such as silicon nitride, silicon oxynitride, and/or silicon oxide, and may include a single-layered structure or a multi-layered structure including the above inorganic insulating materials.

The upper electrode CE2 of the storage capacitor Cst may include a conductive material of a low-resistance material, such as molybdenum (Mo), aluminum (Al), copper (Cu) and/or titanium (Ti), and may have a single-layered structure or a multi-layered structure including the above materials.

A second interlayer insulating layer 207 may be located on the storage capacitor Cst. The second interlayer insulating layer 207 may include an inorganic insulating material, such as silicon nitride, silicon oxynitride, and/or silicon oxide, and may include a single-layered structure or a multi-layered structure including the above inorganic insulating materials.

A semiconductor layer (referred to as a third semiconductor layer A3) of the third thin-film transistor T3 may be located on the second interlayer insulating layer 207. The third semiconductor layer A3 may include an oxide-based semiconductor material. As an example, the third semiconductor layer A3 may include Zn-oxide-based material (e.g., Zn-oxide, In—Zn oxide, and/or Ga—In—Zn oxide). In one or more embodiments, the third semiconductor layer A3 may include In—Ga—Zn—O (IGZO), In—Sn—Zn—O (ITZO), or In—Ga—Sn—Zn—O (IGTZO) semiconductor-containing metal, such as indium (In), gallium (Ga), and/or stannum (Sn) in ZnO.

The third semiconductor layer A3 may include a channel region C3, a first region B3, and a second region D3, wherein the first region B3 and the second region D3 respectively located on two opposite sides of the channel region C3. One of the first region B3 and the second region D3 may correspond to a source region, and the other may correspond to a drain region.

The third thin-film transistor T3 may include a gate electrode (referred to as a third gate electrode GE3, hereinafter) overlapping the channel region C3 of the third semiconductor layer A3. The third gate electrode GE3 may have a double gate structure including a lower gate electrode G3A and an upper gate electrode G3B, wherein the lower gate electrode G3A is below the third semiconductor layer A3, and the upper gate electrode G3B is over the channel region C3.

The lower gate electrode G3A may be on or at the same layer (e.g., the first interlayer insulating layer 205) as the upper electrode CE2 of the storage capacitor Cst. The lower gate electrode G3A may include the same material as a material of the upper electrode CE2 of the storage capacitor Cst.

The upper gate electrode G3B may be located over the third semiconductor layer A3 with a second gate-insulating layer 209 therebetween. The second gate-insulating layer 209 may include an inorganic insulating material, such as silicon nitride, silicon oxynitride, and/or silicon oxide, and may include a single-layered structure or a multi-layered structure including the above inorganic insulating materials.

A third interlayer insulating layer 210 may be located on the upper gate electrode G3B. The third interlayer insulating layer 210 may include an inorganic insulating material, such as silicon oxynitride, and may have a single layer or a multi-layer including the inorganic insulating materials.

Although FIG. 3 shows the first thin-film transistor T1 and the third thin-film transistor T3 among the plurality of thin-film transistors, and shows the first semiconductor layer A1 and the third semiconductor layer A3 are located on/at different respective layers, as described below with reference to FIG. 4, the disclosure is not limited thereto.

The second, fifth, sixth, and seventh thin-film transistors T2, T5, T6, and T7 described below with reference to FIG. 4 may have the same structure as the first thin-film transistor T1 described with reference to FIG. 3. As an example, the second, fifth, sixth, and seventh thin-film transistors T2, T5, T6, and T7 may include a semiconductor layer located on or at the same layer as the first semiconductor layer A1 of the first thin-film transistor T1, and a gate electrode located on or at the same layer as the first gate electrode GE1 of the first thin-film transistor T1. The semiconductor layers of the second, fifth, sixth, and seventh thin-film transistors T2, T5, T6, and T7 may be integrally connected to the first semiconductor layer A1.

The fourth thin-film transistor T4 (see FIG. 4) described below with reference to FIG. 4 may have the same structure as that of the third thin-film transistor T3 described with reference to FIG. 3. As an example, the fourth thin-film transistor T4 may include a semiconductor layer at the same layer as the third semiconductor layer A3 of the third thin-film transistor T3, and a gate electrode formed on or at the same layer as the third gate electrode GE3 of the third thin-film transistor T3. A semiconductor layer of the fourth thin-film transistor T4 may be integrally connected to the third semiconductor layer A3 of the third thin-film transistor T3.

The first thin-film transistor T1 may be electrically connected to the third thin-film transistor T3 through a node connection line 166. The node connection line 166 may be located on the third interlayer insulating layer 210. One side of the node connection line 166 may be connected to the first gate electrode GE1 of the first thin-film transistor T1, and the other side of the node connection line 166 may be connected to the third semiconductor layer A3 of the third thin-film transistor T3.

The node connection line 166 may include aluminum (Al), copper (Cu), and/or titanium (Ti), and may include a single layer or a multi-layer including the above materials. As an example, the node connection line 166 may have a three-layered structure of titanium layer/aluminum layer/titanium layer.

A first organic insulating layer 211 may be located on the node connection line 166. The first organic insulating layer 211 may include an organic insulating material. The organic insulating material may include acryl, benzocyclobutene (BCB), polyimide, or hexamethyldisiloxane (HMDSO).

A second organic insulating layer 212 may be located on the first organic insulating layer 211. In this case, the second organic insulating layer 212 may include a material identical or similar to that of the first organic insulating layer 211. In addition, the second organic insulating layer 212 may be integrally formed with the first organic insulating layer 211, or formed separately from the first organic insulating layer 211 and stacked on the first organic insulating layer 211.

The data line DL and the driving voltage line PL may be located on the first organic insulating layer 211 or the second organic insulating layer 212, and may be covered by the second organic insulating layer 212 or a third organic insulating layer 213. Hereinafter, for convenience of description, the case where the data line DL and the driving voltage line PL are located on the second organic insulating layer 212 and covered by the third organic insulating layer 213 is mainly described in detail.

The data line DL and the driving voltage line PL may include aluminum (Al), copper (Cu), and/or titanium (Ti), and may include a single layer or a multi-layer including the above materials. As an example, the data line DL and the driving voltage line PL may each have a three-layered structure of titanium layer/aluminum layer/titanium layer.

The third organic insulating layer 213 may include acryl, BCB, polyimide, and/or HMDSO. Although it is shown in FIG. 3 that the data line DL and the driving voltage line PL are located on the first organic insulating layer 211, the disclosure is not limited thereto. In one or more other embodiments, one of the data line DL and the driving voltage line PL may be at the same layer (e.g., the third interlayer insulating layer 210) as the node connection line 166.

The light-emitting diode (e.g., the organic light-emitting diode OLED) may be located on the third organic insulating layer 213.

A first electrode 221 of the organic light-emitting diode OLED may include a reflective layer including silver (Ag), magnesium (Mg), aluminum (Al), platinum (Pt), palladium (Pd), gold (Au), nickel (Ni), neodymium (Nd), iridium (Ir), chrome (Cr), or a compound thereof. In one or more other embodiments, the first electrode 221 may further include a conductive oxide material layer on and/or under the reflective layer. The conductive oxide material layer may include indium tin oxide (ITO), indium zinc oxide (IZO), zinc oxide (ZnO), indium oxide (In₂O₃), indium gallium oxide (IGO), and/or aluminum zinc oxide (AZO). In one or more embodiments, the first electrode 221 may have a three-layered structure of ITO layer/Ag layer/ITO layer.

A bank layer 215 may be located on the first electrode 221. The bank layer 215 may include/define an opening that overlaps the first electrode 221, and may cover the edges of the first electrode 221. The bank layer 215 may include an organic insulating material, such as polyimide.

An intermediate layer 222 includes an emission layer 222b. The intermediate layer 222 may include a first functional layer 222a and/or a second functional layer 222c, wherein the first functional layer 222a is under the emission layer 222b, and the second functional layer 222c is above the emission layer 222b. The emission layer 222b may include a polymer organic material or a low-molecular weight organic material configured to emit light having a corresponding color. The second functional layer 222c may include an electron transport layer (ETL) and/or an electron injection layer (EIL). The first functional layer 222a and the second functional layer 222c may each include an organic material.

A second electrode 223 may include a conductive material having a low work function. As an example, the second electrode 223 may include a (semi) transparent layer including silver (Ag), magnesium (Mg), aluminum (Al), platinum (Pt), palladium (Pd), gold (Au), nickel (Ni), neodymium (Nd), iridium (Ir), chrome (Cr), or an alloy thereof. Alternatively, the second electrode 223 may further include a layer on the (semi) transparent layer, the layer including ITO, IZO, ZnO, or In₂O₃.

The emission layer 222b may be formed in the display area DA to overlap the first electrode 221 at the opening of the bank layer 215. In contrast, the first functional layer 222a, the second functional layer 222c, and the second electrode 223 may cover the display area DA entirely.

The spacer 217 may be formed on the bank layer 215. The spacer 217 may be formed together with the bank layer 215 during the same process as a process of forming the bank layer 215, or formed separately during a separate process. In one or more embodiments, the spacer 217 may include an organic insulating material, such as polyimide. Alternatively, the bank layer 215 may include an organic insulating material including a light-blocking dye, and the spacer 217 may include an organic insulating material, such as polyimide.

The organic light-emitting diode OLED may be covered by an encapsulation member 300. In this case, the encapsulation member 300 may include a sealing member 320A and the encapsulation substrate 310A. The sealing member 320A may be formed in a resin form, and may be located and cured on the substrate 100 to couple the substrate 100 and the encapsulation substrate 310A to each other. In addition, because the encapsulation substrate 310A is identical or similar to the substrate 100, detailed description thereof is omitted.

The input-sensing layer 400 may be located on the encapsulation substrate 310A. The input-sensing layer 400 may include touch electrodes TE and at least one touch-insulating layer located in the display area DA. With regard to this, it is shown in FIG. 3 that the input-sensing layer 400 includes a first touch-insulating layer 410, a first conductive line 420, a second touch-insulating layer 430, a second conductive line 440, and a third touch-insulating layer 450, wherein the first touch-insulating layer 410 is on the encapsulation substrate 310A, the first conductive line 420 is on the first touch-insulating layer 410, the second touch-insulating layer 430 is on the first conductive line 420, the second conductive line 440 is on the second touch-insulating layer 430, and the third touch-insulating layer 450 is on the second conductive line 440.

The first touch-insulating layer 410, the second touch-insulating layer 430, and the third touch-insulating layer 450 may each include an inorganic insulating material and/or an organic insulating material. In one or more embodiments, the first touch-insulating layer 410 and the second touch-insulating layer 430 may each include an inorganic insulating material, such as silicon oxide, silicon nitride, and/or silicon oxynitride, and the third touch-insulating layer 450 may include an organic insulating material. At least one of the first touch-insulating layer 410, the second touch-insulating layer 430, and the third touch-insulating layer 450 may extend from the display area DA to the peripheral area PA.

The touch electrode TE of the input-sensing layer 400 may have a structure in which the first conductive line 420 is connected to the second conductive line 440. Alternatively, the touch electrode TE may include one of the first conductive line 420 and the second conductive line 440. In this case, the second touch-insulating layer 430 may be omitted.

Each of the first conductive line 420 and the second conductive line 440 may include aluminum (Al), copper (Cu), and/or titanium (Ti), and may include a single layer or a multi-layer including the above materials. As an example, each of the first conductive line 420 and the second conductive line 440 may have a triple-layered structure of titanium layer/aluminum layer/titanium layer.

FIG. 4 is a circuit diagram of a pixel circuit of the display panel 50 shown in FIG. 1.

Referring to FIG. 4, as described above with reference to FIG. 1, each sub-pixel P (see FIG. 1) may be configured to emit light using a light-emitting diode. The light-emitting diode may be electrically connected to the sub-pixel circuit PC.

The sub-pixel circuit PC may include a first thin-film transistor T1, a second thin-film transistor T2, a third thin-film transistor T3, a fourth thin-film transistor T4, a fifth thin-film transistor T5, a sixth thin-film transistor T6, a seventh thin-film transistor T7, and a storage capacitor Cst.

The second thin-film transistor T2 is a switching thin-film transistor, may be connected to a scan line SL and a data line DL, and may be configured to transfer a data voltage (or a data signal Dm) to the first thin-film transistor T1 based on a switching voltage (or a switching signal Sn), the data voltage being input from the data line DL, and the switching voltage being input from the scan line SL.

The storage capacitor Cst may be connected to the second thin-film transistor T2 and the driving voltage line PL, and may be configured to store a voltage corresponding to a difference between a voltage transferred from the second thin-film transistor T2 and a driving voltage ELVDD supplied to the driving voltage line PL.

The first thin-film transistor T1 is a driving thin-film transistor, may be connected to the driving voltage line PL and the storage capacitor Cst, and may be configured to control a driving current according to the voltage stored in the storage capacitor Cst, the driving current flowing from the driving voltage line PL to a light-emitting diode LED.

The light-emitting diode LED may be configured to emit light having a brightness corresponding to the driving current. A second electrode (e.g., a cathode) of the light-emitting diode LED may be configured to receive a common voltage ELVSS.

The third thin-film transistor T3 is a compensation thin-film transistor, and a gate electrode of the third thin-film transistor T3 may be connected to the scan line SL. A source electrode (or a drain electrode) of the third thin-film transistor T3 may be connected to a first electrode of the light-emitting diode LED through the sixth thin-film transistor T6 while being connected to a drain electrode (or a source electrode) of the first thin-film transistor T1. A drain electrode (or a source electrode) of the third thin-film transistor T3 may be connected to one of the electrodes of the storage capacitor Cst, a source electrode (or a drain electrode) of the fourth initialization thin-film transistor T4, and the gate electrode of the first thin-film transistor T1. The third thin-film transistor T3 is turned on according to a scan signal Sn received through the scan line SL and diode-connects the first thin-film transistor T1 by connecting the gate electrode and the drain electrode of the first thin-film transistor T1 to each other.

The fourth thin-film transistor T4 is an initialization thin-film transistor, and a gate electrode thereof may be connected to a previous scan line SL-1. A drain electrode (or a source electrode) of the fourth thin-film transistor T4 may be connected to an initialization voltage line VL. A drain electrode (or a source electrode) of the fourth thin-film transistor T4 may be connected to one of the electrodes of the storage capacitor Cst, a drain electrode (or a source electrode) of the third initialization thin-film transistor T3, and the gate electrode of the first thin-film transistor T1. The fourth thin-film transistor T4 may be turned on according to a previous scan signal Sn-1 received through the previous scan line SL-1, and may perform an initialization operation of initializing the voltage of the gate electrode of the first thin-film transistor T1 by transferring an initialization voltage Vint to the gate electrode of the first thin-film transistor T1.

The fifth thin-film transistor T5 is an operation control thin-film transistor, and a gate electrode thereof may be connected to an emission control line EL. A source electrode (or a drain electrode) of the fifth thin-film transistor T5 may be connected to the driving voltage line PL. The drain electrode (or the source electrode) of the fifth thin-film transistor T5 may be connected to the source electrode (or the drain electrode) of the first thin-film transistor T1, and the drain electrode (or the source electrode) of the second thin-film transistor T2.

The sixth thin-film transistor T6 is an emission control thin-film transistor, and a gate electrode thereof may be connected to the emission control line EL. A source electrode (or a drain electrode) of the sixth thin-film transistor T6 may be connected to the drain electrode (or the source electrode) of the first thin-film transistor T1, and the source electrode (or the drain electrode) of the third thin-film transistor T3. The drain electrode (or the source electrode) of the sixth thin-film transistor T6 may be electrically connected to the first electrode of the light-emitting diode LED. The fifth thin-film transistor T5 and the sixth thin-film transistor T6 may be concurrently or substantially simultaneously turned on according to an emission control signal En transferred through the emission control line EL, the driving voltage ELVDD is transferred to the light-emitting element LED, and the driving current flows through the light-emitting element LED.

The seventh thin-film transistor T7 may be an initialization thin-film transistor configured to initialize the first electrode of the light-emitting diode LED. A gate electrode of the seventh thin-film transistor T7 may be connected to a next scan line SL+1. The source electrode (or the drain electrode) of the seventh thin-film transistor T7 may be connected to the first electrode of the light-emitting diode LED. The drain electrode (or the source electrode) of the seventh thin-film transistor T7 may be connected to the initialization voltage line VL. The seventh thin-film transistor T7 may be turned on according to a next scan signal Sn+1 transferred through the next scan line SL+1 to initialize the first electrode of the light-emitting element LED.

Although it is shown in FIG. 4 that the fourth thin-film transistor T4 and the seventh thin-film transistor T7 are respectively connected to the previous scan line SL-1 and the next scan line SL+1, both the fourth thin-film transistor T4 and the seventh thin-film transistor T7 may be connected to the previous scan line SL-1 and driven according to a previous scan signal Sn-1, in one or more other embodiments.

The other electrode of the storage capacitor Cst may be connected to the driving voltage line PL. One of the electrodes of the storage capacitor Cst may be connected to the gate electrode of the first thin-film transistor T1, the drain electrode (or the source electrode) of the third thin-film transistor T3, and the source electrode (or the drain electrode) of the fourth thin-film transistor T4 together.

The second electrode (e.g., a cathode) of the light-emitting diode LED is configured to receive the common power voltage ELVSS. The light-emitting diode LED is configured to emit light by receiving the driving current from the first thin-film transistor T1.

The light-emitting diode LED may be an organic light-emitting diode including an organic material as an emission material. In one or more other embodiments, the light-emitting diode LED may be an inorganic light-emitting diode including an inorganic material. The inorganic light-emitting diode may include a PN diode including inorganic material semiconductor-based materials. When a forward voltage is applied to a PN-junction diode, holes and electrons are injected, and energy created by recombination of the holes and the electrons may be converted to light energy, and thus, light of a corresponding color may be emitted. The inorganic light-emitting diode may have a width of several micrometers to hundreds of micrometers, or several nanometers to hundreds of nanometers. In one or more embodiments, the light-emitting diode LED may be a quantum-dot light-emitting diode. As described above, an emission layer of the light-emitting diode LED may include an organic material, an inorganic material, quantum dots, an organic material and quantum dots, or inorganic material and quantum dots. Hereinafter, for convenience of description, the case where the light-emitting diode LED includes an organic light-emitting diode is described.

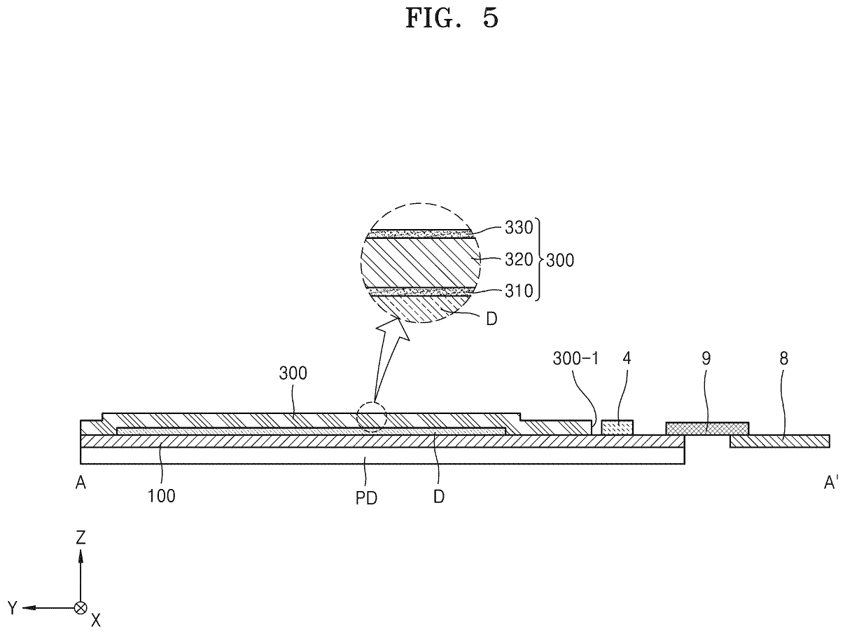

FIG. 5 is a schematic cross-sectional view of the display panel 50 according to one or more other embodiments.

Referring to FIG. 5, the display panel 50 may include the substrate 100, the display layer D, the encapsulation member 300, the protective member PD, the display driver 4, the connection member 9, and the display controller 8. In this case, because the display layer D, the protective member PD, the display driver 4, the connection member 9, and the display controller 8 are identical or similar to those described with reference to FIGS. 1 and 2, repeated detailed descriptions thereof are omitted.

The encapsulation member 300 may be an encapsulation layer. The encapsulation member 300 may include at least one organic encapsulation layer 320 and/or one or more inorganic encapsulation layers 310 and 330. In one or more embodiments, the encapsulation member 300 may include first and second inorganic encapsulation layers 310 and 330 and the organic encapsulation layer 320 therebetween. In this case, the first inorganic encapsulation layer 310 may shield an opposite electrode of FIG. 3, and the organic encapsulation layer 320 and the second inorganic encapsulation layer 330 may be sequentially stacked on the first inorganic encapsulation layer 310.

The first and second inorganic encapsulation layers 310 and 330 may include at least one inorganic material among aluminum oxide, titanium oxide, tantalum oxide, hafnium oxide, zinc oxide, silicon oxide, silicon nitride, silicon oxynitride, or the like. The first and second inorganic encapsulation layers 310 and 330 may include a single layer or a multi-layer including the above materials. The organic encapsulation layer 320 may include a polymer-based material. The polymer-based material may include an acryl-based resin, an epoxy-based resin, polyimide, and polyethylene. In one or more embodiments, the organic encapsulation layer 320 may include acrylate.

The thickness of the first inorganic encapsulation layer 310 may be different from that of the second inorganic encapsulation layer 330. The thickness of the first inorganic encapsulation layer 310 may be greater than that of the second inorganic encapsulation layer 330. Alternatively, the thickness of the second inorganic encapsulation layer 330 may be greater than that of the first inorganic encapsulation layer 310, or the thickness of the first inorganic encapsulation layer 310 may be the same as that of the second inorganic encapsulation layer 330. In addition, in a plan view, a planar shape in which the first inorganic encapsulation layer 310 is located may be inside a planar shape in which the second inorganic encapsulation layer 330 is located. In addition, a planar shape in which the first inorganic encapsulation layer 310 is located, and a planar shape in which the second inorganic encapsulation layer 330 is located, may be the same to overlap each other in a plan view. In this case, the planar shape of the organic encapsulation layer 320 may be located inside the planar shape of the first inorganic encapsulation layer 310.

In this case, the encapsulation member 300 may have an equal or similar shape to the planar shape of the encapsulation substrate 310A shown in FIG. 1 or the planar shape of the edge of the sealing member 320A shown in FIG. 1. That is, the edge of the encapsulation member 300 or the edge of the sealing member 320A may correspond to the edge of the encapsulation substrate 310A shown in FIG. 1. In this case, the edge of the encapsulation member 300 may include/define an opening 310A-1. In this case, the edge of the encapsulation member 300 or the edge of the sealing member 320A may be the edge of the first inorganic encapsulation layer 310 or the edge of the second inorganic encapsulation layer 330. Hereinafter, for convenience of description, the case where the edge of the encapsulation member 300 or the edge of the sealing member 320A is the edge of the second inorganic encapsulation layer 330 is mainly described in detail.

In this case, the second inorganic encapsulation layer 330 may shield the display area DA entirely, and may shield the peripheral area PA partially. As an example, the second inorganic encapsulation layer 330 may shield all of the left, right, and the upper ends of the substrate 100 shown in FIG. 1. In contrast, under the substrate 100 of FIG. 1, a portion of the second inorganic encapsulation layer 330 may shield the end of the substrate 100, and another portion of the second inorganic encapsulation layer 330 may form the opening 300-1 recessed from the end of the substrate 100 as shown in FIG. 1. The opening 300-1 may expose the display driver 4 to the outside. In this case, the encapsulation member 300 may reduce the area in which at least one of wirings is not shielded by the encapsulation member 300, as described with reference to FIGS. 1 and 2.

Although it is described in one or more embodiments that the second inorganic encapsulation layer 330 extends up to the end of a portion of the substrate 100, the present disclosure is not limited thereto, and the end of the second inorganic encapsulation layer 330 may be located between the end of the substrate 100 and the display area DA. In this case, the second inorganic encapsulation layer 330 may include/define the opening 300-1 described above.

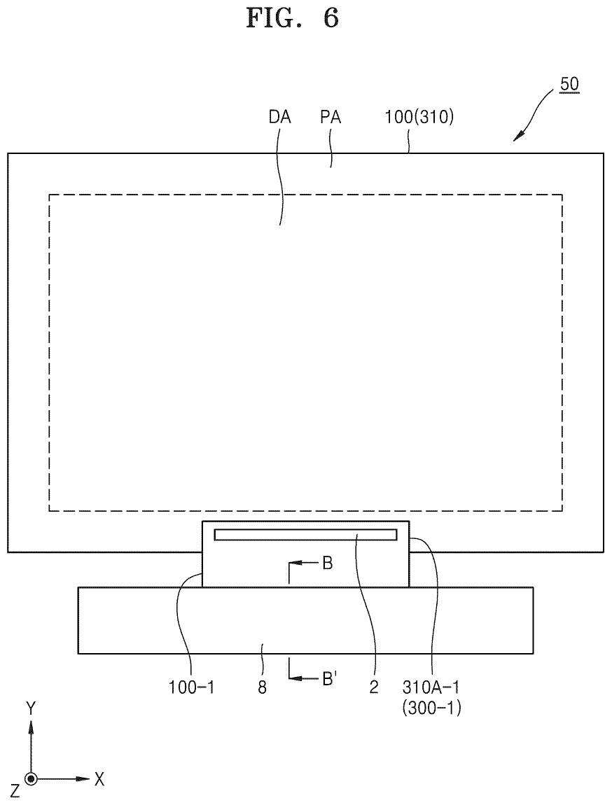

FIG. 6 is a schematic plan view of the display panel 50 according to one or more other embodiments.

Referring to FIG. 6, the display panel 50 may include the substrate 100, the display layer D located in the display area DA, the encapsulation member 300, the display driver 4, and the display controller 8. In this case, because the substrate 100, the display layer D, the display driver 4, and the display controller 8 are identical or similar to those described with reference to FIGS. 1 and 2, repeated detailed descriptions thereof are omitted. In addition, the substrate 100 may include the substrate protrusion 100-1. In this case, because the substrate protrusion 100-1 is identical or similar to that described with reference to FIGS. 1 and 2, repeated detailed descriptions thereof are omitted. In one or more embodiments, as shown in FIG. 1, a scan line SL, a data line DL, a first scan driver 3a, a second scan driver 3b, a driving voltage supply line 6, a common voltage supply line 7, and each wiring may be located in the peripheral area PA.

As shown in FIG. 2, the encapsulation member 300 may include a sealing member 320A, and the encapsulation substrate 310A as shown in FIG. 2. In this case, the encapsulation substrate 310A may include/define the opening 310A-1. In one or more other embodiments, in the case where the encapsulation member 300 is an encapsulation layer, a second inorganic encapsulation layer (e.g., second inorganic encapsulation layer 330 in FIG. 5) of the encapsulation member 300 may include/define an opening 300-1.

The display controller 8 may be directly connected to the substrate 100. In this case, a plurality of terminals may be located on the substrate 100, and the plurality of terminals may be directly electrically connected to the display controller 8.

In this case, the display driver 4 of the display panel 50 may be exposed to the outside. In this case, the encapsulation member 300 may shield most of each wiring connected to the terminal as described with reference to FIGS. 1 and 2.

Accordingly, in the display panel 50, because an area in which each wiring is exposed to the outside is reduced, damage or destruction of each wiring may be reduced or prevented.

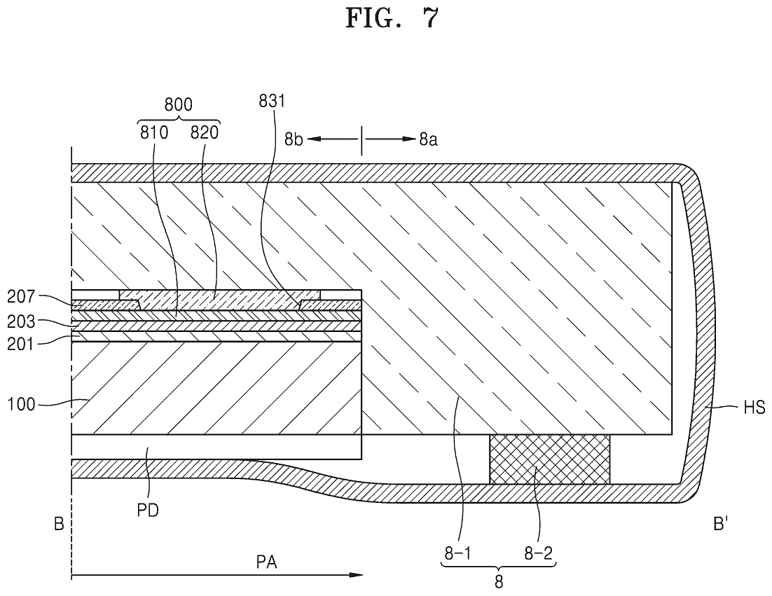

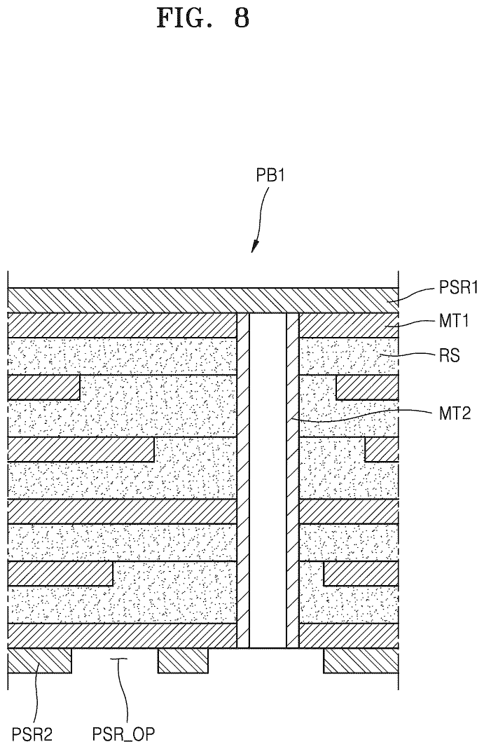

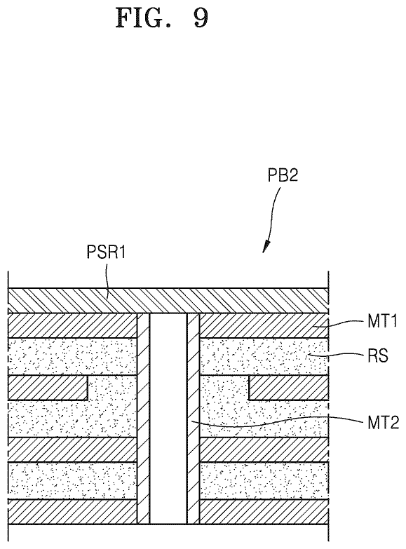

FIG. 7 is a cross-sectional view of the display panel 50, taken along the line B-B′ of FIG. 6. FIG. 7 is a schematic cross-sectional view of a portion of the display panel 50, and the display controller 8 shown in FIG. 6. FIG. 8 is a schematic cross-sectional view of a first region of FIG. 7. FIG. 9 is a schematic cross-sectional view of a second region of FIG. 7.

Referring to FIG. 7, at least a portion of the display controller 8 may be stepped. As an example, the display controller 8 may include a first board region 8a and a second board region 8b with different thicknesses. In this case, the first board region 8a may be a region facing the lateral surface of the substrate 100, and the second board region 8b may be a region located on the upper surface of the substrate 100.

In this case, a plurality of pad terminals 800 may be located on the end portion of the substrate 100 in the peripheral area PA of the display panel 50. The plurality of pad terminals 800 may be apart from each other in one direction of the substrate 100.

The pad terminal 800 may include a first conductive layer 810 and a second conductive layer 820. The buffer layer 201 may be located on the substrate 100 in the peripheral area PA in which the pad terminal 800 is located. In addition, the first gate-insulating layer 203 may be located on the buffer layer 201.

The first conductive layer 810 provided to each pad terminal may be located on the first gate-insulating layer 203. In one or more embodiments, the first conductive layer 810 may be electrically connected to a wiring drawn from the display area DA. The first conductive layer 810 may be located on or at the same layer as the first gate electrode GE1. That is, the first conductive layer 810 may include the same material as that of the first gate electrode GE1, and may be formed during the same process as a process of forming the first gate electrode GE1. The first conductive layer 810 and the first gate electrode GE1 may be apart from each other in one direction of the substrate 100.

A second interlayer insulating layer 207 may be located on the first conductive layer 810. The second interlayer insulating layer 207 may cover at least a portion of the first conductive layer 810. A contact hole 831 may be formed in, or defined by, the first conductive layer 810 by removing a portion of the second interlayer insulating layer 207. The upper surface of the first conductive layer 810 may be exposed to the outside through a region in which the contact hole 831 is formed.

The second conductive layer 820 may be located on the first conductive layer 810. The second conductive layer 820 may be located in an island form on the first conductive layer 810. In one or more other embodiments, the second conductive layer 820 may be electrically connected to a wiring drawn from the display area DA.

The second conductive layer 820 may be located on or at the same layer as a source electrode and a drain electrode. That is, the second conductive layer 820 may include the same material as that of the source electrode and the drain electrode, and may be formed during the same process as a process of forming the source electrode and the drain electrode. In one or more embodiments, the second conductive layer 820 may have a structure in which a plurality of layers including at least one of aluminum (Al) or titanium (Ti) are stacked. The second conductive layer 820 may have a stack structure of Al/Ti/Al or Ti/Al/Ti. However, various embodiments may be made. In this case, the second conductive layer 820 is not limited thereto and may include other materials or other structures.

The second conductive layer 820 may be electrically connected to the first conductive layer 810 through the contact hole 831. That is, the second conductive layer 820 may be electrically connected to the first conductive layer 810 in a region where the second interlayer insulating layer 207 is not present.

A portion of the display controller 8 may be located on the pad terminal 800, and thus may be directly connected to the pad terminal 800. As an example, the display controller 8 may include a display circuit board 8-1 and a display component 8-2. The display circuit board 8-1 may include at least one first metal layer MT1 and/or at least one resin layer RS. In the case where the display circuit board 8-1 includes at least one first metal layer MT1 and/or at least one resin layer RS, the plurality of first metal layers MT1 and the plurality of resin layers RS may be alternately located with each other. In this case, the first metal layer MT1 may be located on the outer surface of the display circuit board 8-1. In this case, each first metal layer MT1 may be formed in various patterns and connected to another.

The display circuit board 8-1 may be directly connected to the pad terminal 800. The display circuit board 8-1 may further include a second metal layer MT2, a first ink layer PSR1, and a second ink layer PSR2. The second metal layer MT2 may connect the first metal layers MT1, which are apart from each other, to each other. For example, the second metal layer MT2 may electrically connect the upper surface to the lower surface of the display circuit board 8-1 by connecting two first metal layers MT1 located on the outermost portion of the display circuit board 8-1. The first ink layer PSR1 may be located on the uppermost side in the second board region 8b of the display circuit board 8-1, and the second ink layer PSR2 may not be located on the lowermost side. In addition, the first ink layer PSR1 may be located on the upper surface of the display circuit board 8-1 in the first board region 8a, and the second ink layer PSR2 may be located on the lower surface of the display circuit board 8-1. In this case, the second ink layer PSR2, which is located on the lower surface of the display circuit board 8-1 in the first board region 8a, may provide a contact space between the display component 8-2 and the first metal layer MT1 by defining an ink opening PSR_OP that partially exposes the first metal layer MT1.

The first metal layer MT1 located on/below the lower surface of the display circuit board 8-1 in the first board region 8a may be exposed to the outside, and may be directly connected to the pad terminal 800. That is, the first metal layer MT1 located on the lower surface of the display circuit board 8-1 may be directly connected to the pad terminal 800. In this case, the first metal layer MT1 connected to the pad terminal 800 may be connected to the first metal layer MT1 located on the upper surface of the display circuit board 8-1 through the second metal layer MT2. In addition, the first metal layer MT1 located on the upper surface of the display circuit board 8-1 may be connected to the first metal layer MT1 located on the lower surface of the display circuit board 8-1 through the second metal layer MT1 located in the first board region 8a, and the first metal layer MT1 may be connected to the display component 8-2.

In this case, the number of first metal layers MT1 and the number of resin layers RS located in the first board region 8a may be greater than the number of first metal layers MT1 and the number of resin layers RS located in the second board region 8b. Through this, the thickness of the display circuit board 8-1 in the first board region 8a may be greater than the thickness of the display circuit board 8-1 in the second board region 8b. In this case, the display component 8-2 may be located in the first board region 8a.

A housing HS may be located in a portion where the display controller 8 is located. The housing HS may surround the display panel 50. In this case, in one or more embodiments, the housing HS may be located on the lower surface of the display panel.

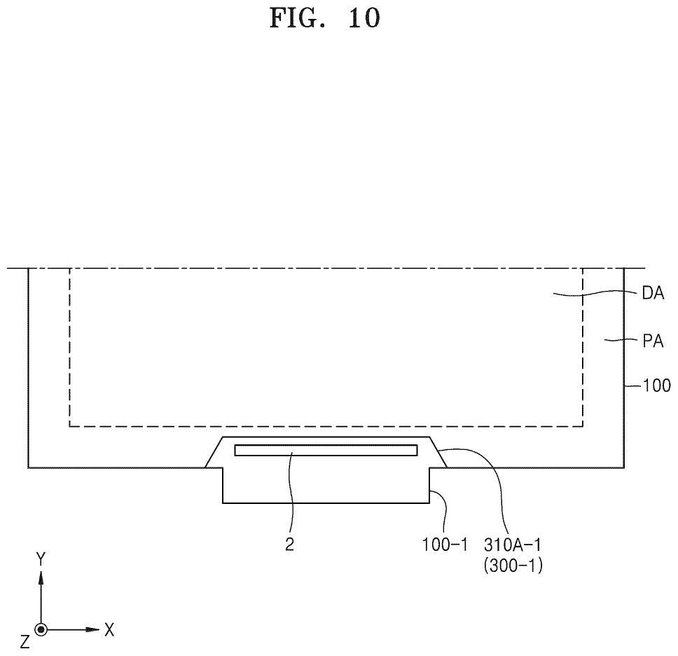

FIG. 10 is a schematic plan view of a portion of the display panel 50 according to one or more other embodiments.

Referring to FIG. 10, the display panel 50 may include the substrate 100, the display layer (e.g., display layer D in FIG. 2) located in the display area DA, the encapsulation member 300, the display driver 4, and the display controller (e.g., display controller 8 in FIG. 2). In this case, because the substrate 100, the display layer, the display driver 4, and the display controller are identical or similar to those described with reference to FIGS. 1 and 2, repeated detailed descriptions thereof are omitted. In addition, the substrate 100 may include the substrate protrusion 100-1. In this case, because the substrate protrusion 100-1 is identical or similar to that described with reference to FIGS. 1 and 2, repeated detailed descriptions thereof are omitted. In one or more embodiments, as shown in FIG. 1, a scan line, a data line, a first scan driver, a second scan driver, a driving voltage supply line, a common voltage supply line, and each wiring may be located in the peripheral area PA.

As shown in FIG. 2, the encapsulation member 300 may include a sealing member 320A, and the encapsulation substrate 310A as shown in FIG. 2. In this case, the encapsulation substrate 310A may include/define the opening 310A-1. In one or more other embodiments, in the case where the encapsulation member 300 is an encapsulation layer, as shown in FIG. 5, a second inorganic encapsulation layer 330 of the encapsulation member 300 may include/define an opening 300-1.

At least a portion of the opening 300-1 or 310A-1 may be formed in an oblique line. As an example, the lateral surface of the opening 300-1 or 310A-1 may be formed in an oblique line. In this case, the planar shape of the lateral surface of the opening 300-1 or 310A-1 may have a trapezoidal shape. In this case, the planar shape of the lateral surface of the opening 300-1 or 310A-1 is not limited thereto, and in one or more embodiments, the planar shape may be various shapes, such as a portion of an elliptical shape and/or a portion of a circle. In this case, the planar shape of the lateral surface of the opening 300-1 or 310A-1 may include all shapes exposing the display driver 4 to the outside.

The display controller may be connected to the substrate 100 through the connection member 9 as shown in FIG. 1, or directly connected to the substrate 100 as shown in FIG. 6.

Accordingly, in the display panel 50, because an area in which each wiring is exposed to the outside is reduced, damage or destruction of each wiring may be reduced or prevented.

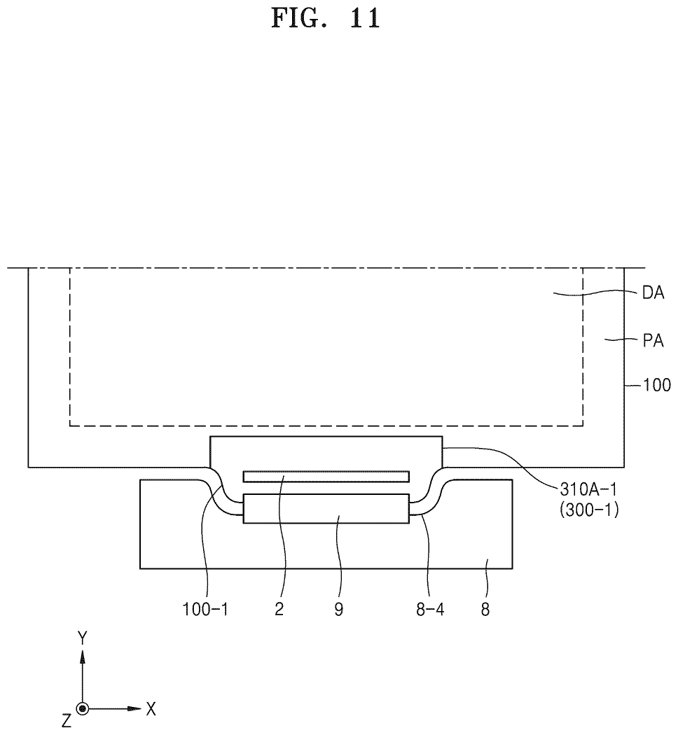

FIG. 11 is a schematic plan view of a portion of the display panel 50 according to one or more other embodiments.

Referring to FIG. 11, the display panel 50 may include the substrate 100, the display layer D located in the display area DA, the encapsulation member 300, the display driver 4, the connection member 9, and the display controller 8. In this case, because the substrate 100, the display layer D, the display driver 4, and the connection member 9 are identical or similar to those described with reference to FIGS. 1 and 2, repeated detailed descriptions thereof are omitted. In addition, the substrate 100 may include the substrate protrusion 100-1. In this case, because the substrate protrusion 100-1 is identical or similar to that described with reference to FIGS. 1 and 2, repeated detailed descriptions thereof are omitted. In one or more embodiments, as shown in FIG. 1, a scan line, a data line, a first scan driver, a second scan driver, a driving voltage supply line, a common voltage supply line, and each wiring may be located in the peripheral area PA.

The display controller 8 may include or define a recess 8-4 to correspond to the substrate protrusion 100-1. In this case, the recess 8-1 may be recessed from the lateral surface of the display controller 8 in a direction away from the substrate protrusion 100-1. Because the exterior of the recess 8-4 is formed to be identical or similar to the exterior of the substrate protrusion 100-1, a distance between the exterior of the recess 8-4 and the exterior of the substrate protrusion 100-1 may be almost constant over the entire recess 8-4 (e.g., a width of the recess 8-4 may be substantially constant).

In this case, the connection member 9 may be located between the substrate protrusion 100-1 and the recess 8-1 to electrically connect the substrate 100 to the display controller 8. In this case, terminals to which the connection member 9 is electrically connected may be located on the substrate protrusion 100-1.

As shown in FIG. 2, the encapsulation member 300 may include a sealing member 320A and the encapsulation substrate 310A as shown in FIG. 2. In this case, the encapsulation substrate 310A may include/define the opening 310A-1. In one or more other embodiments, in the case where the encapsulation member 300 is an encapsulation layer as shown in FIG. 5, a second inorganic encapsulation layer 330 of the encapsulation member 300 may include/define an opening 300-1. In this case, the openings 300-1 and 310A-1 may be identical or similar to the form described with reference to FIG. 1, 6, or 10.

Accordingly, in the display panel 50, because an area in which each wiring is exposed to the outside is reduced, damage or destruction of each wiring may be reduced.

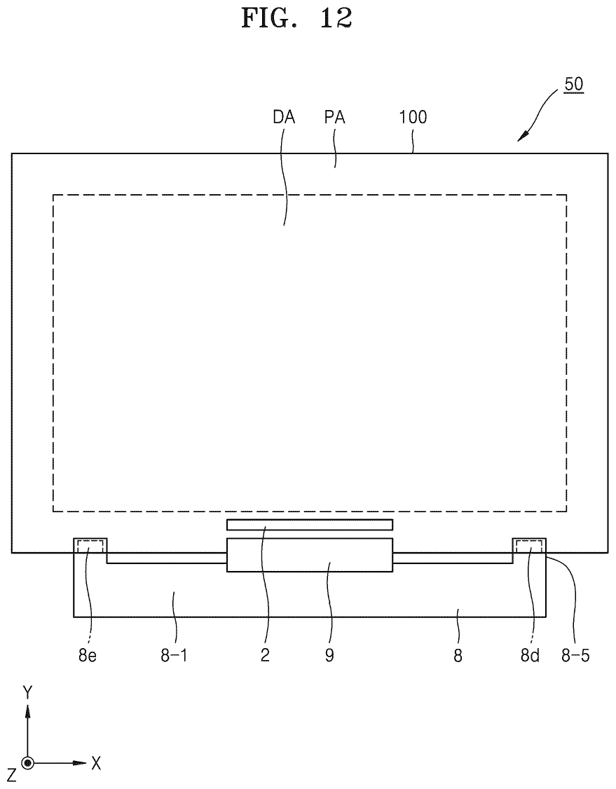

FIG. 12 is a schematic plan view of the display panel 50 according to one or more other embodiments.

Referring to FIG. 12, the display panel 50 may include the substrate 100, the display layer D located in the display area DA, the encapsulation member 300, the display driver 4, the connection member 9, and the display controller 8. In this case, because the substrate 100, the display layer D, the display driver 4, and the connection member 9 are identical or similar to those described with reference to FIGS. 1 and 2, repeated detailed descriptions thereof are omitted. In addition, the encapsulation member 300 may include a sealing member 320A, and an encapsulation substrate (e.g., the encapsulation substrate 310A in FIG. 1) similar to those described with reference to FIGS. 1 and 2. In one or more other embodiments, similar to that described with reference to FIG. 6, the encapsulation member 300 may be an encapsulation layer. In this case, the encapsulation member 300 may or may not include/define an opening 300-1 described with reference to FIGS. 1 to 11.

In one or more embodiments, as shown in FIG. 1, a scan line, a data line, a first scan driver, a second scan driver, a driving voltage supply line, a common voltage supply line, and each wiring may be located in the peripheral area PA.

The display controller 8 may include a display circuit board 8-1 and a connector 8-5. In this case, various components, such as a semiconductor chip may be located on the display circuit board 8-1. The connector 8-5 may protrude from the display circuit board 8-1 toward the substrate 100. In this case, the display controller 8 may have a ‘C’ shape. The connector 8-5 may be a rigid-flexible printed circuit board (RF-PCB). In this case, the substrate 100 and the connector 8-5 may be integrally formed with each other, and the substrate 100 may be a circuit board PCB.

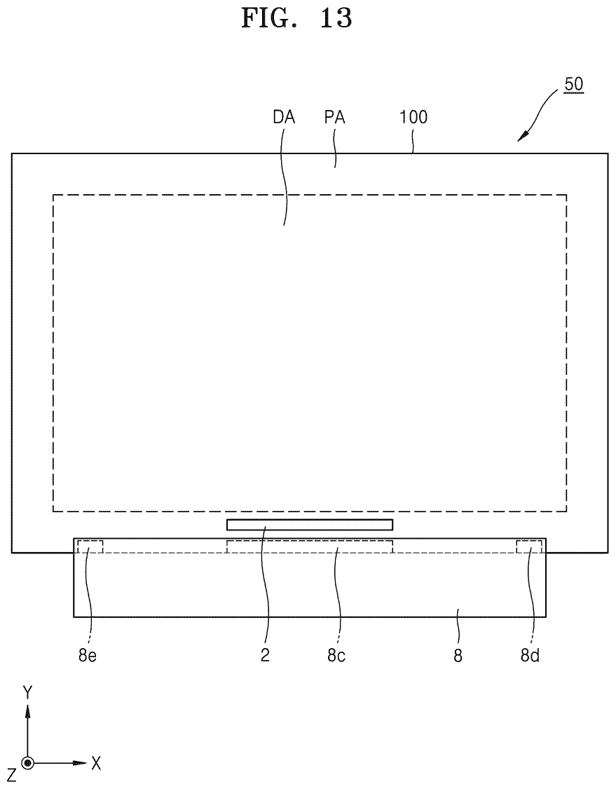

In this case, the display controller 8 may be directly connected to the substrate 100 through at least a second portion. As an example, the display controller 8 may be connected to the substrate 100 in a first region (e.g., see first region 8c of FIG. 13), a second region 8d, and a third region 8e. In this case, in the first region, the display controller 8 may be electrically connected to the substrate 100 by the connector 9. In contrast, in the second region 8d and the third region 8e, the connector 8-5 may be directly connected to the substrate 100. In this case, the terminals described with reference to FIG. 1 may be located on the lower surface of the substrate 100 in FIG. 12. In this case, the terminals connected to the connection member 9 may be mainly connected to a wiring connected to the display driver 4. In addition, the terminals connected to the connector 8-5 in the second region 8d and the third region 8e may be connected to a wiring connected to at least one of the driving voltage supply line or the common voltage supply line shown in FIG. 1.

In this case, in operation, the display panel 50 may stably supply a voltage through the driving voltage supply line and the common voltage supply line. In this case, the display panel 50 may implement images having a uniform brightness on the entire display area DA.

FIG. 13 is a schematic plan view of the display panel 50 according to one or more other embodiments.

Referring to FIG. 13, the display panel 50 may include the substrate 100, the display layer D located in the display area DA, the encapsulation member 300, the display driver 4, and the display controller 8. In this case, because the substrate 100, the display layer, and the display driver 4 are identical or similar to those described with reference to FIGS. 1 and 2, repeated detailed descriptions thereof are omitted. In addition, the encapsulation member 300 may include a sealing member 320A, and an encapsulation substrate 310A similar to those described with reference to FIGS. 1 and 2. In one or more other embodiments, similar to that described with reference to FIG. 6, the encapsulation member 300 may be an encapsulation layer. In this case, the encapsulation member 300 may or may not include/define an opening 300-1 described with reference to FIGS. 1 to 11.

In one or more embodiments, as shown in FIG. 1, a scan line, a data line, a first scan driver, a second scan driver, a driving voltage supply line, a common voltage supply line, and each wiring may be located in the peripheral area PA.

The display controller 8 may be directly connected to the substrate 100. In this case, the display controller 8 may be connected to a terminal on the substrate 100 in at least a second portion. As an example, the display controller 8 may be directly connected to the terminal on the substrate 100 in the first region 8c, the second region 8d, and the third region 8e. In this case, in the first region 8c, the terminals connected to the wiring connected to the display driver 4 may be connected to the display controller 8 as described with reference to FIG. 12. In addition, in the second region 8d and the third region 8e, terminals connected to a wiring mainly connected to at least one of the driving voltage supply line or the common voltage supply line shown in FIG. 1 may be connected to the display controller 8.

In this case, in operation, the display panel 50 may stably supply a voltage through the driving voltage supply line and the common voltage supply line. In this case, the display panel 50 may implement images having a uniform brightness on the entire display area DA.

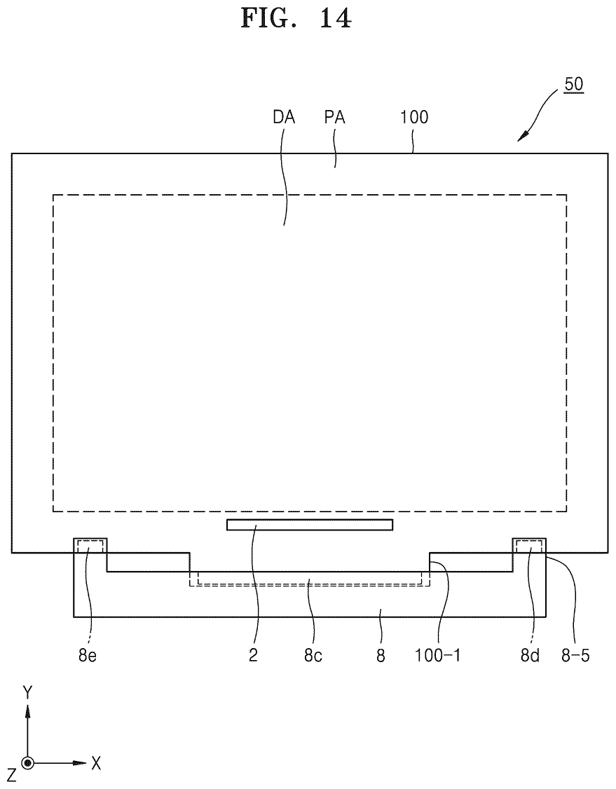

FIG. 14 is a schematic plan view of the display panel 50 according to one or more other embodiments.

Referring to FIG. 14, the display panel 50 may include the substrate 100, the display layer D located in the display area DA, the encapsulation member 300, the display driver 4, and the display controller 8. In this case, because the substrate 100, the display layer, and the display driver 4 are identical or similar to those described with reference to FIGS. 1 and 2, repeated detailed descriptions thereof are omitted. In addition, the encapsulation member 300 may include a sealing member 320A, and an encapsulation substrate 310A similar to those described with reference to FIGS. 1 and 2. In one or more other embodiments, similar to that described with reference to FIG. 6, the encapsulation member 300 may be an encapsulation layer. In this case, the encapsulation member 300 may or may not include/define an opening 300-1 described with reference to FIGS. 1 to 11.

In one or more embodiments, as shown in FIG. 1, a scan line, a data line, a first scan driver, a second scan driver, a driving voltage supply line, a common voltage supply line, and each wiring may be located in the peripheral area PA.

In this case, the substrate 100 may include the substrate protrusion 100-1. In this case, the substrate protrusion 100-1 may protrude from a portion of the substrate 100 in a direction away from the display area DA.

In this case, the terminals located on the substrate 100 may be directly connected to the display controller 8. In this case, the display controller 8 may be similar to the form shown in FIG. 12. In addition, the display controller 8 may be directly connected to the terminals in at least the second portion. That is, the connector 8-5 of the display controller 8 may be directly connected to the terminals of the substrate 100 the second region 8d and the third region 8e. In addition, in the first region 8c located in the substrate protrusion 100-1, the display controller 8 may be directly connected to the terminals of the substrate 100. In this case, the terminals located in the first region 8c, the second region 8d, and the third region 8e may be connected to each element in the same or similar way as described with reference to FIGS. 12 and 10. As an example, in the first region 8c, the terminals connected to the wiring connected to the display driver 4 may be connected to the display controller 8 as described with reference to FIG. 12. In addition, in the second region 8d and the third region 8e, terminals connected to a wiring mainly connected to at least one of the driving voltage supply line or the common voltage supply line shown in FIG. 1 may be connected to the display controller 8.

In this case, in operation, the display panel 50 may stably supply a voltage through the driving voltage supply line and the common voltage supply line. In this case, the display panel 50 may implement images having a uniform brightness on the entire display area DA.

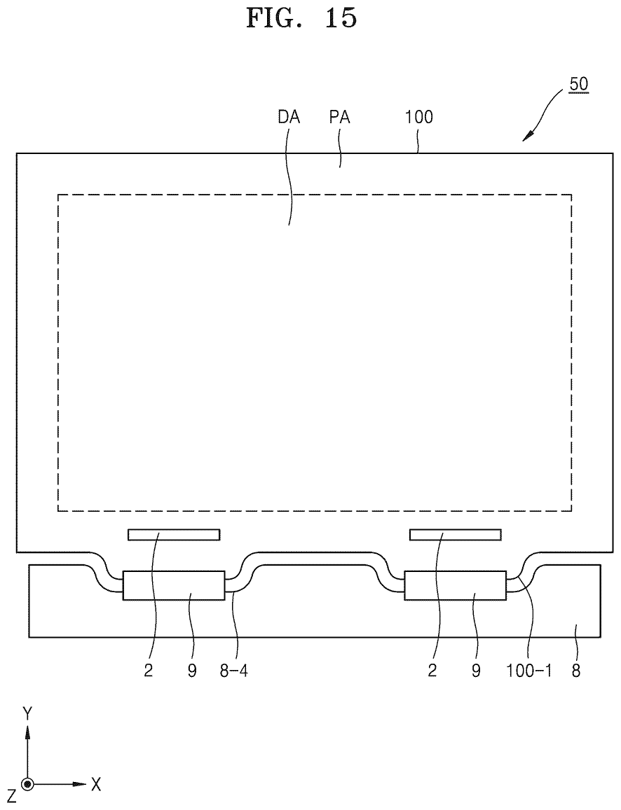

FIG. 15 is a schematic plan view of the display panel 50 according to one or more other embodiments.

Referring to FIG. 15, the display panel 50 may include the substrate 100, the display layer D located in the display area DA, the encapsulation member 300, the display driver 4, the connection member 9, and the display controller 8. In this case, because the substrate 100, the display layer D, the display driver 4, and the connection member 9 are identical or similar to those described with reference to FIGS. 1 and 2, repeated detailed descriptions thereof are omitted. In addition, the encapsulation member 300 may include a sealing member 320A, and an encapsulation substrate 310A similar to those described with reference to FIGS. 1 and 2. In one or more other embodiments, similar to that described with reference to FIG. 6, the encapsulation member 300 may be an encapsulation layer. In this case, the encapsulation member 300 may or may not include/define an opening 300-1 described with reference to FIGS. 1 to 11.

In one or more embodiments, as shown in FIG. 1, a scan line, a data line, a first scan driver, a second scan driver, a driving voltage supply line, a common voltage supply line, and each wiring may be located in the peripheral area PA.

In this case, the substrate 100 may include at least two substrate protrusions 100-1. Hereinafter, for convenience of description, the case where the substrate 100 includes two substrate protrusions 100-1 is mainly described in detail.

The display controller 8 may include at least two recesses 8-4 corresponding to each substrate protrusion 100-1. In this case, each recess 8-4 may have a shape corresponding to each substrate protrusion 100-1. Hereinafter, for convenience of description, the case where the display controller 8 includes two recesses 8-4 is mainly described in detail.

The display driver 4 may be located on each substrate protrusion 100-1. In this case, the terminals may be located on each substrate protrusion 100-1, and each terminal may be connected to a wiring connected to the display driver 4, the first scan driver, the second scan driver, the driving voltage supply line, or the common voltage supply line. In this case, the terminals located on each substrate protrusion 100-1 may be connected to a wiring connected to the display driver 4, the first scan driver, the second scan driver, the driving voltage supply line, or the common voltage supply line located relatively close to each substrate protrusion 100-1 through each connection member 9.

In this case, in operation, the display panel 50 may stably supply a voltage to each part of the display area DA through the driving voltage supply line and the common voltage supply line. In this case, the display panel 50 may implement images having a uniform brightness on the entire display area DA.

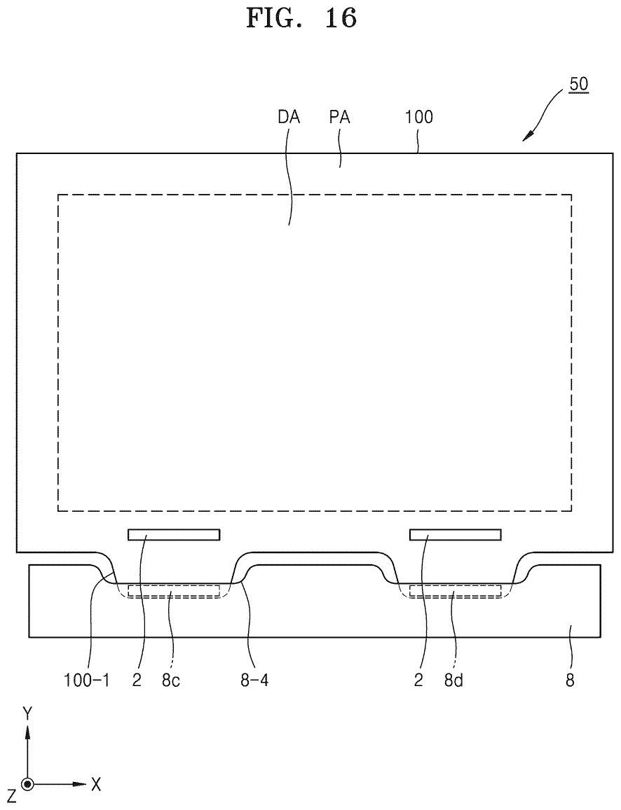

FIG. 16 is a schematic plan view of the display panel 50 according to one or more other embodiments.

Referring to FIG. 16, the display panel 50 may include the substrate 100, the display layer D located in the display area DA, the encapsulation member 300, the display driver 4, the connection member 9, and the display controller 8. In this case, because the substrate 100, the display layer D, the display driver 4, and the connection member 9 are identical or similar to those described with reference to FIGS. 1 and 2, repeated detailed descriptions thereof are omitted. In addition, the encapsulation member 300 may include a sealing member 320A, and an encapsulation substrate 310A similar to those described with reference to FIGS. 1 and 2. In one or more other embodiments, similar to that described with reference to FIG. 6, the encapsulation member 300 may be an encapsulation layer. In this case, the encapsulation member 300 may or may not include/define an opening 300-1 described with reference to FIGS. 1 to 11.

In one or more embodiments, as shown in FIG. 1, a scan line, a data line, a first scan driver, a second scan driver, a driving voltage supply line, a common voltage supply line, and each wiring may be located in the peripheral area PA.

In this case, the substrate 100 may include at least two substrate protrusions 100-1. Hereinafter, for convenience of description, the case where the substrate 100 includes two substrate protrusions 100-1 is mainly described in detail.

The display controller 8 may include at least two recesses 8-4 corresponding to each substrate protrusion 100-1. In this case, each recess 8-4 may have a shape corresponding to each substrate protrusion 100-1. In one or more other embodiments, the display controller 8 may not include the recess 8-4. That is, the display controller 8 may be formed in a similar way shown in FIG. 13. Hereinafter, for convenience of description, the case where the display controller 8 includes two recesses 8-4 is mainly described in detail.

The terminals located on each substrate protrusion 100-1 may be directly connected to the display controller 8. As an example, the terminals located on each substrate protrusion 100-4 may be directly connected, in the first region 8c and the second region 8d, to the display controller 8 on which each recess 8-4 is located.

In this case, in the first region 8c and the second region 8d, the display controller 8 may be directly connected to the terminal connected to the wiring connected to the display driver 4, the first scan driver, the second scan driver, the driving voltage supply line, or the common voltage supply line located relatively close to the first region 8c and the second region 8d.

In this case, in the display area DA close to the first region 8c and the second region 8d, a voltage for driving sub-pixels may be stably supplied.

Accordingly, the display panel 50 may implement images having a uniform brightness on the entire display area DA. In addition, electrical characteristics of the display panel 50 may be improved.

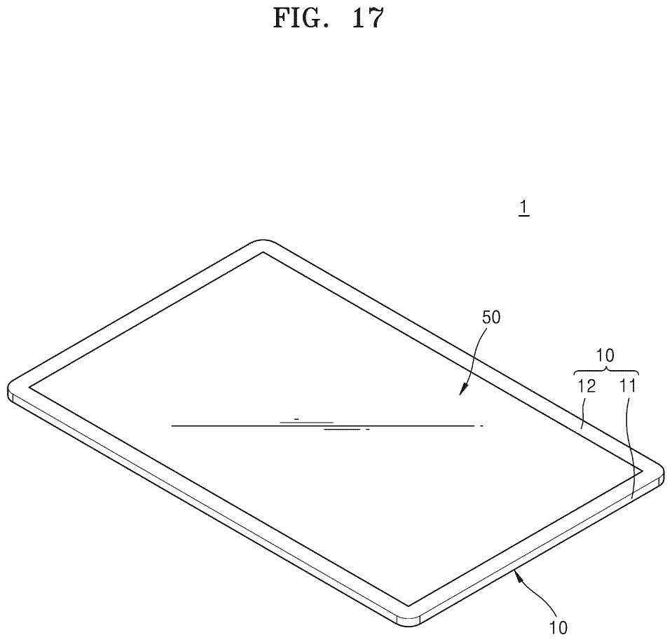

FIG. 17 is a schematic perspective view of an electronic apparatus 1 including a display panel according to embodiments.

Referring to FIG. 17, the electronic apparatus 1 may include an apparatus for displaying moving images or still images or various products including televisions, notebook computers, monitors, advertisement boards, Internet of things (IoTs) as well as portable electronic apparatuses including mobile phones, smartphones, tablet personal computers (PCs), mobile communication terminals, electronic organizers, electronic books, portable multimedia players (PMPs), navigations, or ultra mobile personal computers (UMPCs). In addition, the electronic apparatus 1 may be wearable devices including smartwatches, watchphones, glasses-type displays, or head-mounted displays (HMDs). In addition, the electronic apparatus 1 may be instrument panels for automobiles, center fascias for automobiles, or center information displays (CIDs) arranged on a dashboard, room mirror displays that replace side mirrors of automobiles, or an entertainment system arranged on the backside of front seats for backseat passengers in automobiles.

The electronic apparatus 1 may include a housing 10 and the display panel 50. The housing 10 may form a rear surface exterior of the electronic apparatus 1. The housing 10 may include plastic, metal, or both plastic and metal. The display panel 50 may be received in the housing 10. The housing 10 may include a main housing 11 in which the display panel 50 is located, and a cover housing 12 coupled to the main housing 11. In this case, the cover housing 12 may include an opaque material.

The display panel 50 may be identical or similar to that described above.

In one or more embodiments, the electronic apparatus 1 may further include an optical functional layer located on the upper surface of the display panel 50. In addition, in the electronic apparatus 1, an input-sensing layer (e.g., input-sensing layer 400 in FIG. 3) receiving a touch signal from a user may be further located between the optical functional layer and the display panel 50. The optical functional layer may include an anti-reflection layer. The anti-reflection layer may reduce reflectivity of light (external light) incident through the display apparatus 1 from the outside.

In one or more embodiments, the anti-reflection layer may include a polarizing film. The polarizing film may include a linear polarizing plate and a phase-retarding film, such as a λ/4 (quarter-wave) plate. The phase-retarding film may be located on a touchscreen layer, and the linear polarizing plate may be located on the phase-retarding film.

In one or more embodiments, the anti-reflection layer may include a filter layer including a black matrix and color filters. The color filters may be arranged by taking into account colors of light emitted respectively from the sub-pixels of the display panel 50. As an example, the filter layer may include a red, blue, or green color filter.

In one or more embodiments, the anti-reflection layer may include a destructive interference structure. The destructive interference structure may include a first reflection layer and a second reflection layer respectively located on different layers. First-reflected light and second-reflected light respectively reflected by the first reflection layer and the second reflection layer may destructively interfere and thus the reflectivity of external light may be reduced.

The electrical characteristics of the display panel and the electronic apparatus according to embodiments are improved.

In the display panel and the electronic apparatus according to embodiments, damage or destruction of a wiring located between the display area and the display driver may be reduced.

In the display panel and the electronic apparatus according to embodiments, the connection between the display panel and the display controller may be firmly maintained.

The display panel and the electronic apparatus according to embodiments may implement clear images on the display panel.

It should be understood that embodiments described herein should be considered in a descriptive sense only and not for purposes of limitation. Descriptions of aspects within each embodiment should typically be considered as available for other similar aspects in other embodiments. While one or more embodiments have been described with reference to the figures, it will be understood by those of ordinary skill in the art that various changes in form and details may be made therein without departing from the spirit and scope as defined by the following claims, with functional equivalents thereof to be included therein.

What is claimed is:

1. A display panel comprising:
a substrate;
a display layer above the substrate;
a display driver above the substrate, and apart from the display layer; and
an encapsulation member above the display layer, configured to shield the display layer and the substrate, and defining an opening recessed toward the display layer to expose the display driver.

2. The display panel of claim 1, wherein the substrate comprises a substrate protrusion protruding away from the display layer to correspond to a portion on which the display driver is located.

3. The display panel of claim 2, further comprising a display controller connected to the substrate, configured to transfer a signal to the display driver, and defining a recess recessed away from the substrate protrusion to correspond to the substrate protrusion.

4. The display panel of claim 2, further comprising a display controller connected to the substrate, configured to transfer a signal to the display driver, and comprising a portion overlapping the substrate protrusion in a plan view.

5. The display panel of claim 1, further comprising a display controller connected to the substrate, and configured to transfer a signal to the display driver.

6. The display panel of claim 1, wherein the encapsulation member comprises:
an encapsulation substrate facing the substrate, and defining the opening; and
a sealing member between the encapsulation substrate and the substrate.

7. The display panel of claim 1, wherein the encapsulation member covers the display layer and defines the opening.

8. The display panel of claim 1, wherein at least a portion of a planar shape of the opening is an oblique line.

9. A display panel comprising:
a substrate comprising a display area and a peripheral area;
a display driver in the peripheral area; and
a display controller connected to the substrate, and configured to transfer a signal to the display driver,
wherein the display controller is in direct contact with the substrate and connected to the substrate in at least two portions.

10. The display panel of claim 9, wherein the display controller comprises:
a display circuit board; and
a connector protruding from the display circuit board toward the substrate, and integrally formed with the display circuit board.

11. The display panel of claim 10, further comprising a connection member apart from the connector, and connecting the display circuit board to the substrate.

12. The display panel of claim 9, wherein the substrate comprises a substrate protrusion protruding toward the display controller.

13. The display panel of claim 12, wherein the display driver is above the substrate such that at least a portion thereof overlaps the substrate protrusion.

14. The display panel of claim 12, wherein the display controller defines a recess recessed in a direction away from the substrate protrusion, and having a shape corresponding to the substrate protrusion.

15. The display panel of claim 9, wherein at least a portion of the display controller overlaps the substrate.

16. An electronic apparatus comprising:
a housing; and
a display panel inside the housing, and comprising:
a substrate;
a display layer above the substrate;
an encapsulation member above the display layer, shielding the display layer and the substrate, and defining an opening recessed toward the display layer; and
a display driver above the substrate, apart from the display layer, and exposed by the opening.

17. The electronic apparatus of claim 16, wherein the substrate comprises a substrate protrusion protruding in a direction away from the display layer to correspond to a location of the display driver.

18. The electronic apparatus of claim 17, further comprising a display controller connected to the substrate, configured to transfer a signal to the display driver, and defining a recess recessed in a direction away from the substrate protrusion and having a shape corresponding to the substrate protrusion.

19. The electronic apparatus of claim 16, wherein the encapsulation member comprises:
an encapsulation substrate facing the substrate, and defining the opening; and
a sealing member between the encapsulation substrate and the substrate.

20. The electronic apparatus of claim 16, wherein the encapsulation member covers the display layer, and defines the opening.
